(19) United States
(12) Patent Application Publication
(10) Pub. No.: US 2017/0352403 A1
(43) Pub. Date: Dec. 7, 2017

(54) MEMORY CONTROLLER, AND MEMORY MODULE AND PROCESSOR INCLUDING THE SAME

(71) Applicants: MemRay Corporation, Seoul (KR); YONSEI UNIVERSITY, UNIVERSITY - INDUSTRY FOUNDATION (UIF), Seoul (KR)

(72) Inventors: Jaesoo LEE, Incheon (KR); Myoungsoo JUNG, Incheon (KR); Gyuyoung PARK, Incheon (KR)

(21) Appl. No.: 15/214,580

(22) Filed: Jul. 20, 2016

(30) Foreign Application Priority Data
Jun. 1, 2016 (KR) 10-2016-0068400

(51) Int. Cl. G11C 11/406; G06F 3/06; G11C 14/00

(52) U.S. Cl. CPC G11C 11/40607; G11C 14/009; G06F 3/0679; G06F 3/0611; G06F 3/0644; G06F 3/0659

(57) ABSTRACT

A memory controller of a memory device that uses a phase change memory and includes a memory cell array partitioned into a plurality of partitions is provided. A write request that request a data write to the memory device and a read request which request a data read from the memory device are inserted to a request queue. A scheduler, in a case that a conflict check condition including a first condition that a write operation is being performed in a first partition among the plurality of partitions is satisfied, creates a read command for a second partition based on a read request for the second partition when the request queue includes the read request for the second partition. The second partition is a partition, in which a read operation does not conflict with the write operation in the first partition, among the plurality of partitions.

### CROSS-REFERENCE TO RELATED APPLICATION

This application claims priority to and the benefit of Korean Patent Application No. 10-2016-0068400 filed in the Korean Intellectual Property Office on Jun. 1, 2016, the entire contents of which are incorporated herein by reference.

### BACKGROUND

### (a) Field

The described technology relates to a memory controller, and a memory module and processor including the same.

### (b) Description of the Related Art

In response to memory devices characterized by high data storage capacity and low power consumption, new memory devices have been developed. These next generation memory devices include, for example, a phase change memory (PCM) that uses a phase change material to store data. A phase-change random access memory (PRAM) is a typical one of the PCMs. The PCM uses the phase change material that can be switched between a crystalline state and an amorphous state, and stores data based on a resistivity difference between the crystalline state and the amorphous state.

While memory cell arrays of the PCM can be partitioned into a plurality of partitions, the partitions are not considered when a scheduling for reading/writing data from/to the memory cell array is performed.

### SUMMARY

An embodiment of the present invention provides a memory controller, and a memory module and processor including the same, for performing a scheduling considering partitions.

According to another embodiment of the present invention, a memory controller of a memory device that uses a phase change memory and includes a memory cell array partitioned into a plurality of partitions is provided. The memory controller includes a request queue and a scheduler. A write request that requests a data write to the memory device and a read request that requests a data read from the memory device are inserted to the request queue. In a case that a conflict check condition including a first condition that a write operation is being performed in a first partition among the plurality of partitions is satisfied, the scheduler creates a read command for a second partition based on a read request for the second partition when the request queue includes the read request for the second partition. The second partition is a partition, in which a read operation does not conflict with the write operation in the first partition, among the plurality of partitions.

The read request used for creating the read command may include a read request that is selected according to a predetermined policy from among read requests for the second partition.

The memory device may further include a plurality of row data buffers that store data read from the memory cell array. When there is a row data buffer which data corresponding to the read request for the second partition hit among the plurality of row data buffers, the scheduler may select the row data buffer.

The memory device may further include a plurality of row data buffers that store data read from the memory cell array. When data corresponding to the read request for the second partition do not hit the plurality of row data buffers, the scheduler may store the data corresponding to the read request for the second partition in a row data buffer that stores oldest data among the plurality of row data buffers.

The conflict check condition may further include a second condition that the request queue does not include a read request for a word line that is open for a read operation while the write operation is being performed in the first partition.

The scheduler may create a read command based on the read request for the open word line when the first condition is satisfied and the second condition is not satisfied.

In a case that the write operation is not being performed in the memory device, the scheduler, when an oldest request in the request queue is a write request, may create a write command based on the oldest write request.

The scheduler may create the write command based on the oldest write request and write requests for memory cells that can be written at the same time with the oldest write request.

In a case that the write operation is not being performed in the memory device, the scheduler, when an oldest request in the request queue is a read request, may create a read command.

The scheduler, when the request queue includes a read request for a word line that is open for a read operation, may create the read command based on the read request for the open word line.

According to yet another embodiment of the present invention, a memory controller of a memory device that uses a phase change memory and includes a memory cell array partitioned into a plurality of partitions is provided. The memory controller includes a request queue and a scheduler. A write request that requests a data write to the memory device and a read request that requests a data read from the memory device are inserted to the request queue. The scheduler creates a read command based on a predetermined read request when a write operation is being performed in a first partition among the plurality of partitions.

The predetermined read request may include a read request for a second partition, in which a read operation does not conflict with the write operation in the first partition, among the plurality of partitions.

The read request used for creating the read command may include a read request that is selected according to a predetermined policy from among read requests for the second partition.

The predetermined read request may include a read request for a word line that is open for a read operation.

In a case that the write operation is not being performed in the memory device, the scheduler, when an oldest request in the request queue is a write request, may create a write command based on the oldest write request.

The scheduler may create the write command based on the oldest write request and write requests for memory cells that can be written at the same time with the oldest write request.

According to still another embodiment of the present invention, a memory module including the memory controller according to any one of the above embodiments and the memory device is provided.

According to further embodiment of the present invention, a processor a memory controller according to any one of the above embodiments is provided. The processor is connected to the memory device through a system bus.

### BRIEF DESCRIPTION OF THE DRAWINGS

FIG. 1 schematically shows one memory cell in a PCM.

FIG. 2 shows a current applied to a memory cell shown in FIG. 1.

FIG. 3 shows a temperature change when a current shown in FIG. 2 is applied to a memory cell shown in FIG. 1.

FIG. 4 is a schematic block diagram of a memory according to an embodiment of the present invention.

FIG. 5 shows an example of partitions according to an embodiment of the present invention.

FIG. 6 shows an example of an overlay window register in a memory according to an embodiment of the present invention.

FIG. 7 and FIG. 8 each schematically show a memory controller according to an embodiment of the present invention.

FIG. 9 is a schematic block diagram of a memory controller according to another embodiment of the present invention.

FIG. 10A and FIG. 10B each are a flowchart showing a request scheduling method in a memory controller according to an embodiment of the present invention.

FIG. 11 is a schematic block diagram of a memory controller according to yet another embodiment of the present invention.

FIG. 12 schematically shows a memory module including a memory controller according to an embodiment of the present invention.

FIG. 13 schematically shows a processor including a memory controller according to an embodiment of the present invention.

### DETAILED DESCRIPTION OF THE EMBODIMENTS

In the following detailed description, only certain embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

While a PRAM is described as an example of a PCM in embodiments of the present invention, embodiments of the present invention are not limited to the PRAM and are applicable to various PCMs.

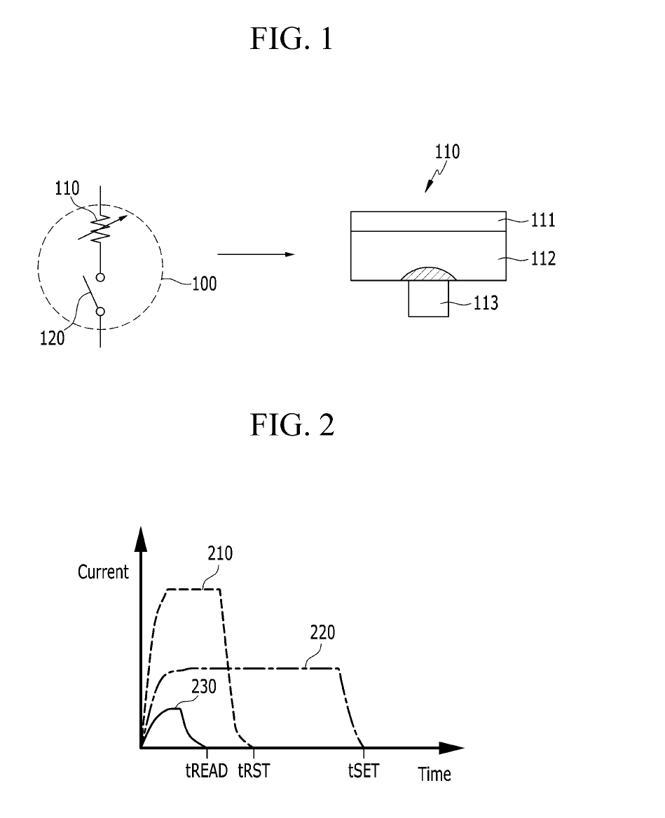

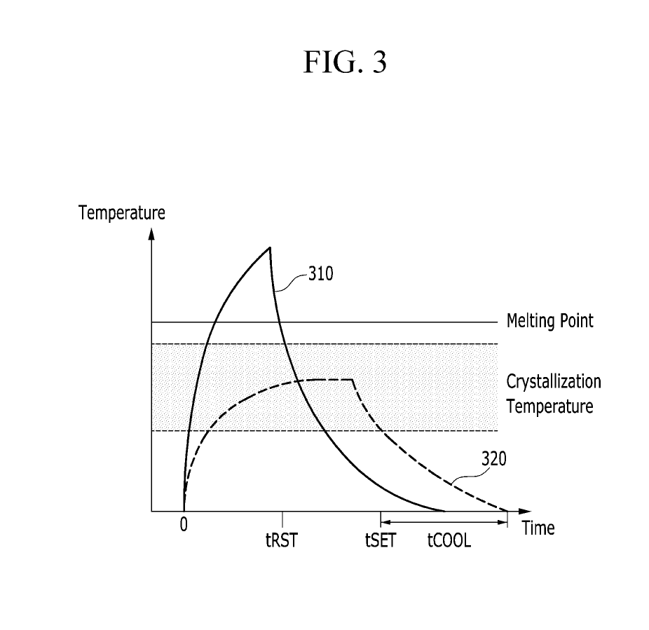

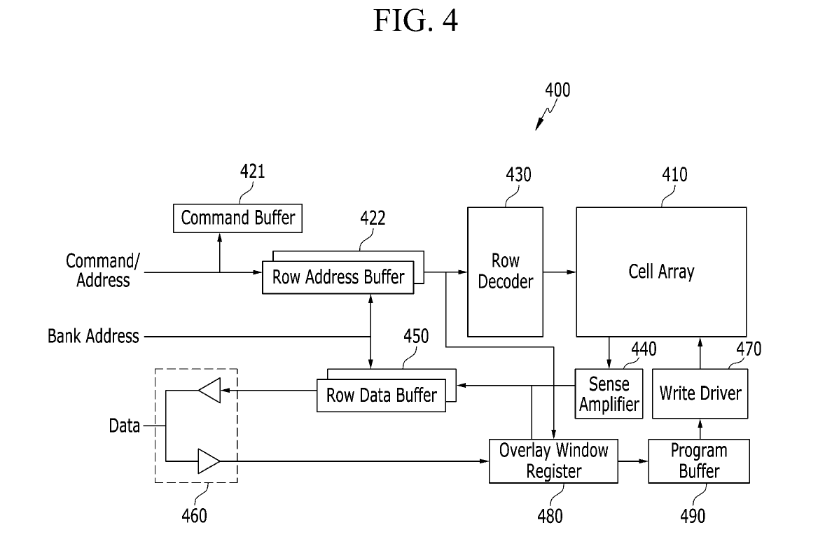

First, a data read/write time in the PRAM is described with reference to FIG. 1, FIG. 2, and FIG. 3.

FIG. 1 schematically shows one memory cell in a PCM, FIG. 2 shows a current applied to a memory cell shown in FIG. 1, and FIG. 3 shows a temperature change when a current shown in FIG. 2 is applied to a memory cell shown in FIG. 1.

The memory cell shown in FIG. 1 is an example memory cell, and a memory cell of the PCM according to embodiments of the present invention may be implemented in various forms.

Referring to FIG. 1, a memory cell 100 of a PRAM includes a phase change element 110 and a switching element 120. The switching element 120 may be implemented with various elements such as a transistor or a diode. The phase change element 110 includes a phase change layer 111, an upper electrode 112 formed above the phase change layer 111, and a lower electrode 113 formed below the phase change layer 111. For example, the phase change layer 110 may include an alloy of germanium (Ge), antimony (Sb) and tellurium (Te), which is referred to commonly as a GST alloy, as a phase change material.

The phase change material can be switched between an amorphous state with relatively high resistivity and a crystalline state with relatively low resistivity. A state of the phase change material may be determined by a heating temperature and a heating time.

Referring to FIG. 1 again, when a current is applied to the memory cell 100, the applied current flows through the lower electrode 113. When the current is applied to the memory cell 100 during a short time, a portion, of the phase change layer 111, adjacent to the lower electrode 113 is heated by the current. The cross-hatched portion of the phase change layer 111 is switched to one of the crystalline state and the amorphous state in accordance with the heating profile of the current. The crystalline state is called a set state and the amorphous state is called a reset state.

Referring to FIG. 2 and FIG. 3, the phase change layer 111 is programmed to the reset state when a reset current 210 with a high current is applied to the memory cell 100 during a short time tRST. If a temperature 310 of the phase change material reaches a melting point as the phase change material of the phase change layer 111 is heated by the applied reset current 210, the phase change material is melted and then is switched to the amorphous state. The phase change layer 111 is programmed to the set state when a set current 220 being lower than the reset current 210 is applied to the memory cell 100 during a time tSET being longer than the time tRST. If a temperature 330 of the phase change material reaches a crystallization temperature as the phase change material is heated by the applied set current 220, the phase change material is melted and then is transformed to the crystalline state. Since the reset state and the set state can be maintained when a current is applied with being lower than the set current 220 or with being shorter than the set current 220, data can be programmed to the memory cell 100.

The reset state and the set state may be set to data of “1” and “0,” respectively, and the data may be sensed by measuring the resistivity of the phase change element 110 in the memory cell 100. Alternatively, the reset state and the set state may be set to data of “0” and “1,” respectively.

Therefore, the data stored in the memory cell 100 can be read by applying a read current 230 to the memory cell 100. The read current 230 is applied with a low magnitude during a very short time tREAD such that the state of the memory cell 100 is not changed. The magnitude of the read current 230 may be lower than the magnitude of the set current 220, and the applied time of the read current 230 may be shorter than the applied time tRST of the reset current 210. Because the resistivity of the phase change element 110 in the memory cell 100 is different according to the state of the phase change element 110, the state of the phase change element 110, i.e., the data stored in the memory cell 100, can be read by a magnitude of a current flowing to the phase change element 110 or a voltage drop on the phase change element 110.

In one embodiment, the state of the memory cell 100 may be read by a voltage at the memory cell 100 when the read current 230 is applied. In this case, since the phase change element 110 of the memory cell 100 has a relatively high resistance in the reset state, the state may be determined to the reset state in a case that the voltage sensed at the phase change element 110 is relatively high and to the set state in a case that the voltage sensed at the phase change element 110 is relatively low. In another embodiment, the state of the memory cell 100 may be read by an output current when a voltage is applied to the memory cell 100. In this case, the state may be determined to the reset state in a case that the current sensed at the phase change element 110 is relatively low and to the set state in a case that the current sensed at the phase change element 110 is relatively high.

Generally, a plurality of memory cells 100 are arranged in a substantially matrix format to form a memory cell array, and data are simultaneously written to memory cells formed on a plurality of columns at the same row. Accordingly, the reset current 210 may be supplied to memory cells 100 to be switched to the reset state and then the set current 220 may be supplied to memory cells 100 to be switched to the set state, in order to write data to the memory cells 100 formed on the plurality of columns In this case, a program time tPGM for writing the data is a time (tRST+tSET) corresponding to a sum of an applied time tRST of the reset current 210 and an applied time tSET of the set current 220. Alternatively, when the reset current 210 and the set current 220 are simultaneously applied, the program time tPGM for writing the data is a time max(tRST,tSET) corresponding to a maximum value of the applied time tRST of the reset current 210 and the applied time tSET of the set current 220.

Further, a write driver may increase a voltage for supplying the reset current 210 and the set current 220 and store charges for the increased voltage, in order to apply the reset current 210 and the set current 220 to the memory cells 100. Accordingly, a time tCHG for charge pumping may be required before the reset current 210 or the set current 220 is applied to the memory cells 100.

Referring to FIG. 3 again, a cooling time may be further needed until the phase change material of the memory cell 100 is cooled after being heated. Data may not be successfully read when the data are read from the memory cell 100 before the phase change material is cooled. Accordingly, the cooling time tCOOL may be further required before reading the data.

Therefore, a write latency time tWRT taken for completing the data write may be given as in Equation 1. The write latency time tWRT may be a time that is required until a memory cell 100 becomes a state capable of reading/writing data after starting to program the data to the memory cell 100.

tWRT=tPGM+max(tCHG,tCOOL) Equation 1

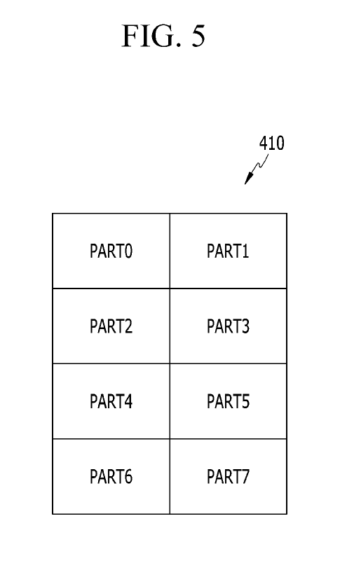

FIG. 4 is a schematic block diagram of a memory according to an embodiment of the present invention, and FIG. 5 shows an example of partitions according to an embodiment of the present invention. A memory shown in FIG. 4 may be a memory chip or a memory bank.

Referring to FIG. 4, a memory 400 includes a memory cell array 410, a command buffer 421, a row address buffer 422, a row decoder 430, a sense amplifier 440, a row data buffer 450, a data input/output (I/O) unit 460, and a write driver 470.

The memory cell array 410 includes a plurality of word lines (not shown) extending substantially in a row direction, a plurality of bit lines (not shown) extending substantially in a column direction, and a plurality of memory cells (not shown) that are connected to the word lines and the bit lines and are formed in a substantially matrix format. The memory cell may be, for example, a memory cell 100 described with reference to FIG. 1. The memory cell array 410 is partitioned into a plurality of partitions. In some embodiments, a partition is a memory cell group in which one operation of a read operation and a write operation can be performed without conflicting with the other operation of the read operation and the write operation in other partitions.

For example, as shown in FIG. 5, a memory cell array 410 may be partitioned into eight partitions PART0-PART7 by being divided into halves in a row direction and into quarters in a column direction. A partitioning method shown in FIG. 5 is an example, and the memory cell array 410 may be partitioned into partitions of various formats. For example, the memory cell array 410 may be partitioned into n*m partitions by being divided into m parts in the row direction and n parts in the column direction. Here, “m” and “n” are an integer that is equal to or greater than one. Sizes of the partitions may be different.

In some embodiments, while a write operation is being performed in one partition (for example, PART0) among the plurality of partitions PART0-PART7, a read operation may be performed in other partitions (for example, PART1-PART7) without conflicting with the write operation of the partition PART0. That is, while the write operation is being performed in the partition PART0 by a row decoder 430 and a write driver 470 corresponding to the partition PART0, the read operation may be performed in a certain partition (for example, PART1) among the other partitions PART1-PART7 by a row decoder 430 and a sense amplifier 440 corresponding to the partition PART1.

In one embodiment, a row decoder 430 may be provided for each partition, and a sense amplifier 440 and a write driver 470 may be shared by at least part of partitions PART0-PART7, for example all the partitions PART0-PART7.

The command buffer 421 and the row address buffer 422 store commands and addresses (particularly, row addresses) from a memory controller. In some embodiments, a plurality of row address buffers 422 may be provided. In one embodiment, a row address buffer 422 may be provided for each bank, and the memory controller may provide a bank address (for example, a buffer number) for addressing the row address buffer 422. In another embodiment, two or more row address buffers 422 may be provided for each bank, and each row address buffer 422 may be addressed by a bank address or a part of the bank address.

The row decoder 430 decodes a row address to select a word line for reading data or writing data from among the plurality of word lines of the memory cell array 410.

The sense amplifier 440 reads data stored in the memory cell array 410. The sense amplifier 440 may read the data, through a plurality of bit lines, from a plurality of memory cells connected to the word line selected by the row decoder 430. The row data buffer 450 stores the data read by the sense amplifier 440. In some embodiments, a plurality of row data buffers 450 may be provided. In one embodiment, a row data buffer 450 may be provided for each bank, and the memory controller may provide a bank address (for example, a buffer number) for addressing the row data buffer 450. In another embodiment, two or more row data buffers 450 may be provided for each bank, and each row data buffer 450 may be addressed by a bank address or a part of the bank address.

The data I/O unit 460 outputs the data that are read by the sense amplifier 440 and stored in the row data buffer 450 to the memory controller. Further, the data I/O unit 460 transfers data that are input from the memory controller to the write driver 470.

The write driver 470 writes the data input from the data I/O unit 460 to the memory cell array 410. The write driver 470 may write the data, through a plurality of bit lines, to a plurality of memory cells connected to the word line selected by the row decoder 430

In some embodiment, the memory 400 may further include an overlay window register 480 and a program buffer 490 as shown in FIG. 4. The overlay window register 480 may control program operations through the program buffer 490. The program buffer 490 may store the data that are input through the data I/O unit 460, and the data stored in the program buffer 490 may be written to the memory cell array 410 through the overlay window register 480. In some embodiments, a memory having a high write speed, for example a static random access memory (SRAM) may be used as the program buffer 490. The overlay window register 480 may include a register for writing the data to a storing position of the program buffer 490.

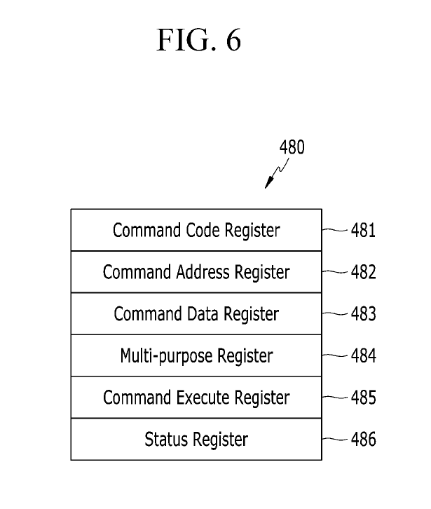

Next, an example of an overlay window register 480 is described with reference to FIG. 6.

Referring to FIG. 6, an overlay window register 480 includes a command code register 481, a command address register 482, a command data register 483, a multi-purpose register 484, a command execute register 485, and a status register 486. These registers 481-486 may be implemented as memory-mapped registers so that they can be accessed by memory controller via memory read/write commands.

A command code, for example a code for program, overwrite, or erase command, is written to the command code register 481. A command address, for example the first data address for a buffered program operation, is written to the command address register 482. Command arguments are written to the command data register 483 and the multi-purpose register 484. Command execution of the overlay window register 480 begins when a predetermined value, for example “0x0001,” is written to the command execute register 485. The status register 486 indicates a status of the memory 400 or a status of program. When the write operation is completed in the memory cell array 410, the status register 486 may indicate a completion status.

For the buffered program operation, the command address indicating the first data address for the buffered program operation is first written to the command address register 482, and then the number of bytes to be programmed is written to the multi-purpose register 484. Next, the program data are written to the program buffer 490, and then the command code indicating the buffered program or buffered overwrite is written to the command code register 481. After the program data are buffered to the program buffer 490, the predetermined value, for example “0x0001,” is written to the command execute register 485 such that the write operation begins. The memory controller may determine whether the write operation is completed by polling the status register 486, i.e., checking the status of the status register 486.

Now, a memory controller according to an embodiment of the present invention is described.

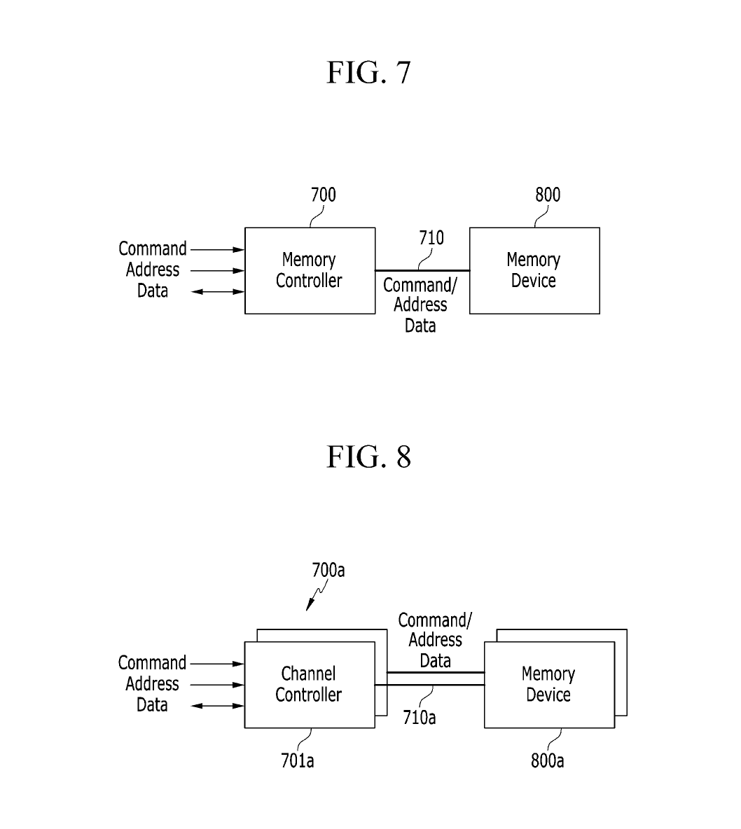

FIG. 7 and FIG. 8 each schematically show a memory controller according to an embodiment of the present invention.

Referring to FIG. 7, a memory controller 700 is connected to a central processing unit (CPU) and a memory device 700, and accesses the memory device 800 in response to a request from the CPU. For example, the memory controller 700 may control a read operation or a write operation of the memory device 800. In some embodiments, the memory device 800 may include a plurality of memory chips.

The memory controller 700 communicates with the CPU through a memory controller interface. The memory controller 700 may receive read/write commands and addresses from the CPU and exchange data with the CPU through the memory controller interface. In some embodiments, the memory controller interface may be a system bus. The system bus may be, for example, a front side bus (FSB), an advanced extensible interface (AXI), or an Avalon bus.

The memory controller 700 may communicate with the memory device 800 through a bus (or a channel) 710 to which the plurality of memory chips are commonly connected. The memory controller 700 may transfer the read/write commands and addresses to the memory device 800 and exchange the data through the channel 510.

Referring to FIG. 8, in some embodiments, a plurality of memory devices 800a each being connected to one or more channels among a plurality of channels 710a may be provided. In this case, a memory controller 700a may include a plurality of channel controllers 701a that are connected to the plurality of channels 710a respectively. Accordingly, a plurality of memory chips included in each memory device 800a may communicate with a corresponding channel controller 701a through a corresponding channel 710a.

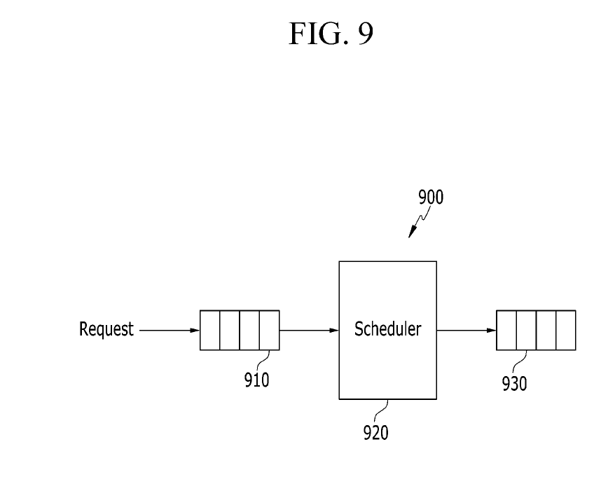

FIG. 9 is a schematic block diagram of a memory controller according to another embodiment of the present invention.

Referring to FIG. 9, a memory controller 900 includes a request queue 910, a scheduler 920, and a command queue 930. When a memory controller includes a plurality of channel controllers as described with reference to FIG. 8, the memory controller 900 shown in FIG. 9 may correspond to a channel controller.

A request, i.e., a write request and a read request, issued from a CPU is inserted to the request queue 910. In some embodiments, the request queue 910 may be implemented by a linked list or a circular buffer. In some embodiments, the request queue 910 may include a read request queue for storing the read requests and a write request queue for storing the write requests.

The scheduler 920 creates a series of memory commands including a read command for reading data from a memory device and a series of memory commands including a write command for writing data to the memory device in accordance with the request, i.e., the read request and the write request, inserted in the request queue 910, and returns completions to the memory controller on the read request and the write request. The scheduler 920 can handle the write request and the read request to allow a read operation to be performed in a partition that does not conflict with a certain partition of a memory cell array in which a write operation is being performed.

The memory commands that are created by the scheduler 920 are inserted to the output command queue 930.

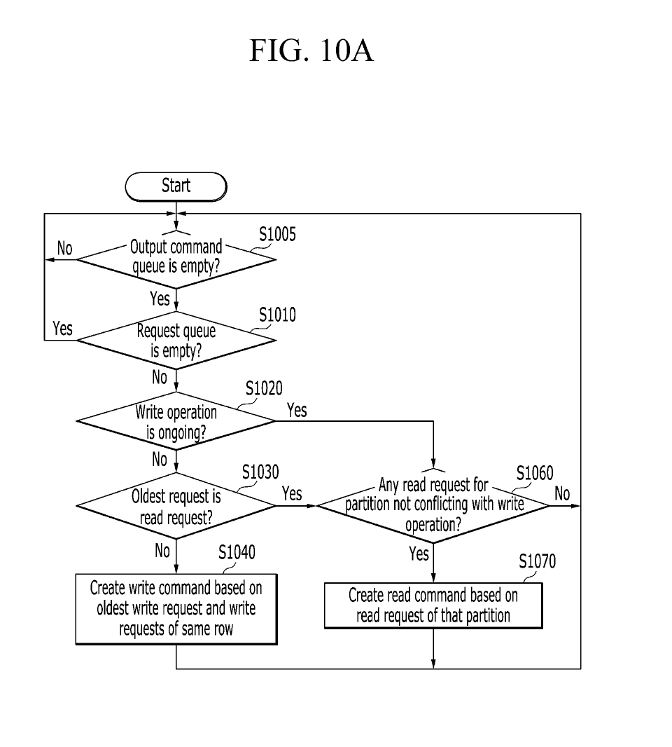

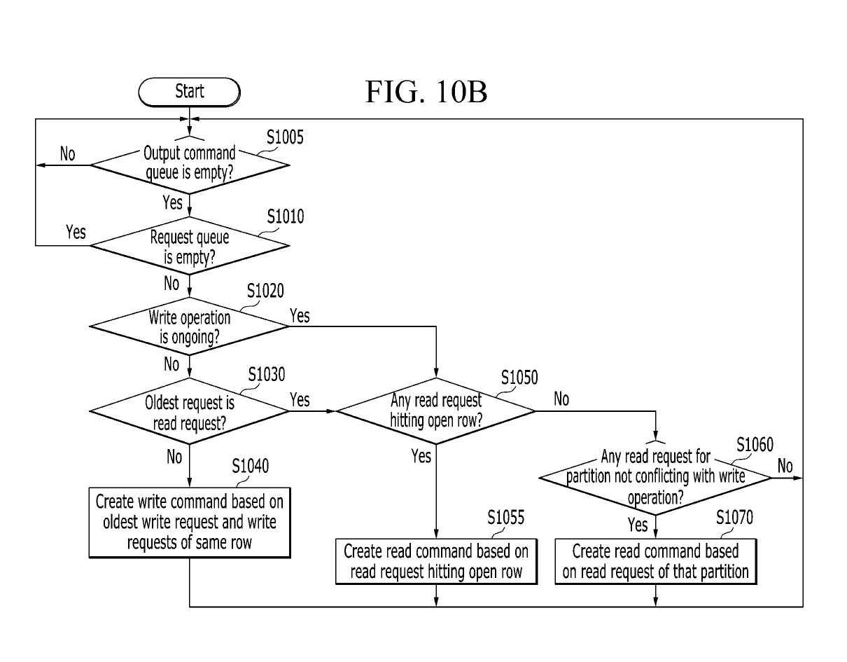

FIG. 10A and FIG. 10B each are a flowchart showing a request scheduling method in a memory controller according to an embodiment of the present invention.

Referring to FIG. 10A, a scheduler 920 checks whether an output command queue 930 is empty (S1005). In one embodiment, the scheduler 920 may check whether the output command queue 930 is truly empty. In another embodiment, the scheduler 920 may check whether the output command queue 930 is empty above a predetermined level.

If the output command queue 930 is empty (S1005: yes), the scheduler 920 performs a scheduling operation for a new command sequence (S1010-S1070). The scheduler 920 first checks whether the request queue 910 is empty (S1010). If the request queue 910 is empty (S1010: yes), the scheduler 920 checks a status of the request queue 910 again for a next scheduling.

If the request queue 910 is not empty (S1010: no), the scheduler 920 checks whether a write operation is being performed in a memory device in accordance with a write request (S1020). If the write operation is not being performed (S1020: no), the scheduler 920 determines whether a request, which is selected according to a predetermined policy among requests inserted to the request queue 910, is a read request or a write request (S1030). In some embodiments, the request selected according to the predetermined policy may be the oldest request among the requests inserted to the request queue 910 as shown in FIG. 10A. Hereinafter, it is assumed that the oldest request is the request selected according to the predetermined policy.

If the selected request is the write request (S1030: no), the scheduler 920 generates one or more memory commands for executing the selected write request, and adds the created commands to the output command queue 930 (S1040). In some embodiments, before generating the memory commands, the scheduler 920 may merge other write requests in the request queue targeting the same program group of memory cells with the selected write request and generate memory commands for the merged write requests. In another embodiment, write requests targeting for the same row may be merged and stored as a burst in the request queue. In this case, because the write requests on the same program group of memory cells (hereinafter referred to as a “memory cell group”) can be simultaneously processed, data can be written to the memory cell group at the same time. Accordingly, the power consumption and time according to frequent memory accesses can be reduced. In some embodiments, the memory cell group may be called as a “page.”

In some embodiments, the memory cells of the page may be positioned at adjacent bit lines. In one embodiment, the memory cells of the page may share the same word line. In some embodiments, a size of the page may be equal to a size of the program buffer 490 shown in FIG. 4. In another embodiment, the size of the page may be greater than or less than the size of the program buffer 490 shown in FIG. 4.

If the write operation is being performed (S1020: yes) or the selected request is the read request (S1030: yes), the scheduler 920 checks whether there is a read request that can be executed (S1060). If a write operation is performed in a partition, a read request whose target partition is not the same as the target partition of the ongoing write operation can be executed. That is, the read request of the partition that does not conflict with the partition in which the write operation is being performed can be executed. If there is no ongoing write operation, a read request for any partition can be executed. The scheduler 920 selects the executable read request, creates memory commands based on the selected read request, and adds the created commands to the output command queue 930 (S1070). In some embodiment, the scheduler may select a read request (for example, the oldest read request) according to the predetermined policy from among the executable read requests. If there is no executable read request (S1060: no), the scheduler 920 may not perform the scheduling and may wait until the write operation is completed or other read request is added to the request queue 910.

In some embodiments, when a plurality of row data buffers 450 are provided in the memory 400, the scheduler 920 may select a row data buffer 450 when processing the read request (S1070). In one embodiment, when there is a row data buffer 450 which data for the read request hit among the row data buffers 450, the scheduler 920 may select the hitting row data buffer 450. The scheduler 920 can read the data stored in the hitting row data buffer 450. In another embodiment, when there is no row data buffer 450 which data for the read request hit among the row data buffers 450, the scheduler may select a least recently used row data buffer 450. The scheduler 920 may evict the oldest data from the selected row data buffer 450 and store data that are read from the memory cell array 410 in the selected row data buffer 450.

In some embodiments, as shown in FIG. 10B, the scheduler 920 may check whether there is a read request that hits an open row of the memory cell array 410 (S1050). The open row may correspond to a word line selected for a read operation among a plurality of word lines of the memory cell array 410. When data for the read request hitting the open row are stored in the row data buffer 450, the scheduler 920 may read the data from the row data buffer 450. If there is the read request hitting the open row (S1050: yes), the scheduler 920 selects the read request hitting the open row, create memory command based on the selected read request, and adds the created memory command to the output command queue 930 (S1055). In one embodiment, the scheduler 920 may select the oldest read request from among the read requests hitting the open row. If there is no read request hitting the open row (S1050: no), the scheduler 920 executes the step S1060. While it has been shown in FIG. 10B that the step S1050 for checking the read request hitting the open row is performed if the write operation is being performed (S1020: yes) or the oldest request is the read request (S1030: yes), the step S1050 may be performed at the other step. For example, the step 1050 may be performed between the steps S1010 and S1020.

It is shown in FIG. 10A and FIG. 10B that the step S1060 is performed in a case that the write operation is being performed (S1020: yes) or the oldest request is the read request (S1030: yes). However, in some embodiments, in a case that the write operation is not being performed and the oldest request is the read request (S1030: yes), the scheduler 920 may determine whether a read request exists in the request queue 910 regardless of the partition conflict (S1060) and create a read command based on a read request selected from the request queue 910 (S1070). In some embodiments, the selected read request may be the oldest read request.

The scheduler 920 may repeat processes for scheduling the read and write requests (S1005-S1070).

As described above, according to an embodiment of the present invention, while the write operation is being performed in the partition in accordance with the write request, the read operation can be simultaneously performed in the other partition without conflicting with the write operation. That is, the scheduling considering the partitions can be performed. For example, if the memory cell array 410 is partitioned into eight partitions and there is no conflict among the partitions, the read request can be processed with a probability of ⅞ when the write operation is being performed in a certain partition.

Since the write time is longer than the read time as described with reference to FIG. 1 to FIG. 3, a depth of the request queue 910 may be deepened in some embodiments. In this case, many read requests can be processed because many read requests can be added to the request queue 910.

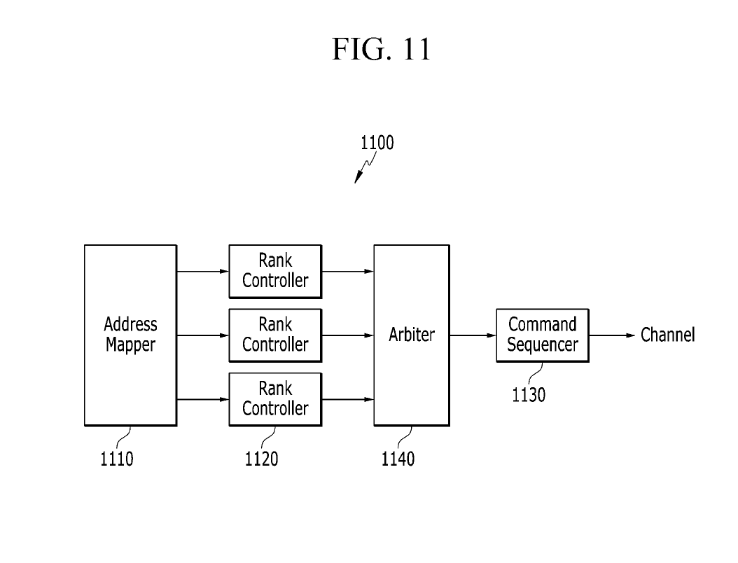

FIG. 11 is a schematic block diagram of a memory controller according to yet another embodiment of the present invention.

Referring to FIG. 11, a memory controller 1100 includes an address mapper 1110, a plurality of rank controllers 1120, an arbiter 1130, and a command sequencer 1140.

A memory device may include a plurality of ranks. In some embodiments, the rank may be a set of memory chips that are independently accessible through a shared channel.

The plurality of ranks may operate independently and may share a channel for commands, addresses, and data. In this case, the memory controller 1100 may include the plurality of rank controllers 1120 that correspond to the plurality of ranks respectively. Each rank controller 1120 may be implemented like the memory controller described with reference to FIG. 7 to FIG. 10.

The address mapper 1110 maps a command (a write request or a read request), an address, and data from the CPU to a rank controller 1120 corresponding to a rank matched to the address from among the plurality of ranks.

The arbiter 1130 arbitrates accesses to the channel referring to a channel status. The arbiter may adjust timings for commands from the plurality of rank controllers 1120. In some embodiments, the arbiter 1130 may consider a row address to column address delay, a charge pumping time, or a column address strobe (CAS) latency time.

In some embodiments, the arbiter 1130 may use a round robin method or a priority-based method as a policy for arbitrating the accesses to the channel.

In some embodiments, a memory controller may be a separate chip (or controller) or be integrated into another chip (or controller). For example, the memory controller may be integrated into a northbridge that manages communications between a CPU and other parts of a motherboard such as a memory device.

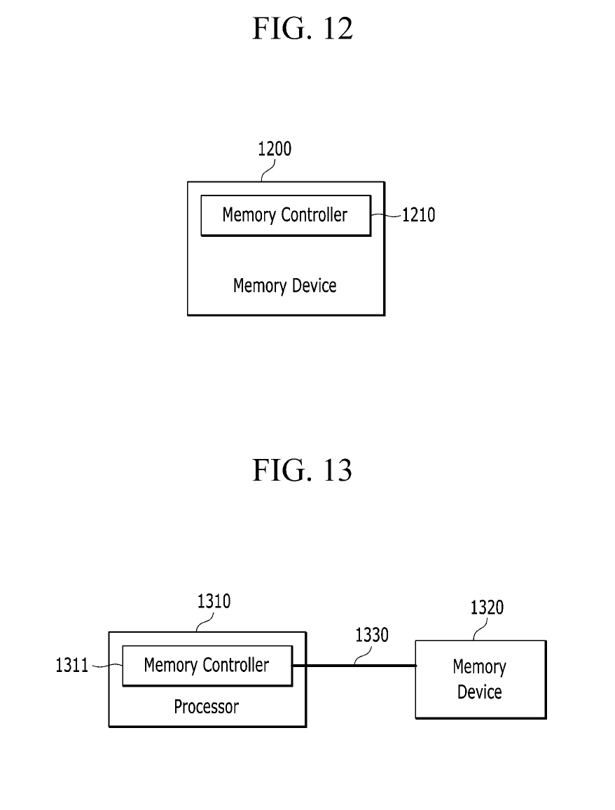

In some embodiments, a memory controller 1210 may be integrated into a memory module 1200 along with a memory device 1220 as shown in FIG. 12. In some embodiments, the memory module 1200 may be a memory module into which a plurality of memory chips are integrated. In one embodiment, the memory module may be a DIMM (dual in-line memory module).

In some embodiments, a memory controller 1311 may be integrated into a processor 1310 such as a CPU as shown in FIG. 13. In one embodiment, the memory controller 1311 may be connected to the processor 1310 via a system bus (not shown) and be connected to a memory device 1320 via a bus (channel) 1330.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A memory controller of a memory device that uses a phase change memory and includes a memory cell array partitioned into a plurality of partitions, the memory controller comprising:
a request queue to which a write request that requests a data write to the memory device and a read request that requests a data read from the memory device are inserted; and
a scheduler that, in a case that a conflict check condition including a first condition that a write operation is being performed in a first partition among the plurality of partitions is satisfied, creates a read command for a second partition based on a read request for the second partition when the request queue includes the read request for the second partition, the second partition being a partition, in which a read operation does not conflict with the write operation in the first partition, among the plurality of partitions.

2. The memory controller of claim 1, wherein the read request used for creating the read command includes a read request that is selected according to a predetermined policy from among read requests for the second partition.

3. The memory controller of claim 1, wherein the memory device further includes a plurality of row data buffers that store data read from the memory cell array, and
wherein the scheduler, when there is a row data buffer which data corresponding to the read request for the second partition hit among the plurality of row data buffers, selects the row data buffer.

4. The memory controller of claim 1, wherein the memory device further includes a plurality of row data buffers that store data read from the memory cell array, and
wherein the scheduler, when data corresponding to the read request for the second partition do not hit the plurality of row data buffers, stores the data corresponding to the read request for the second partition in a row data buffer that stores oldest data among the plurality of row data buffers.

5. The memory controller of claim 1, wherein the conflict check condition further includes a second condition that the request queue does not include a read request for a word line that is open for a read operation while the write operation is being performed in the first partition.

6. The memory controller of claim 5, wherein the scheduler creates a read command based on the read request for the open word line when the first condition is satisfied and the second condition is not satisfied.

7. The memory controller of claim 1, wherein in a case that the write operation is not being performed in the memory device, the scheduler, when an oldest request in the request queue is a write request, creates a write command based on the oldest write request.

8. The memory controller of claim 7, wherein the scheduler creates the write command based on the oldest write request and write requests for memory cells that can be written at the same time with the oldest write request.

9. The memory controller of claim 1, wherein in a case that the write operation is not being performed in the memory device, the scheduler, when an oldest request in the request queue is a read request, creates a read command.

10. The memory controller of claim 9, wherein the scheduler, when the request queue includes a read request for a word line that is open for a read operation, creates the read command based on the read request for the open word line.

11. A memory controller of a memory device that uses a phase change memory and includes a memory cell array partitioned into a plurality of partitions, the memory controller comprising:
a request queue to which a write request that requests a data write to the memory device and a read request that requests a data read from the memory device are inserted; and
a scheduler that creates a read command based on a predetermined read request when a write operation is being performed in a first partition among the plurality of partitions.

12. The memory controller of claim 11, wherein the predetermined read request includes a read request for a second partition, in which a read operation does not conflict with the write operation in the first partition, among the plurality of partitions.

13. The memory controller of claim 12, wherein the read request used for creating the read command includes a read request that is selected according to a predetermined policy from among read requests for the second partition.

14. The memory controller of claim 11, wherein the predetermined read request includes a read request for a word line that is open for a read operation.

15. The memory controller of claim 11, wherein in a case that the write operation is not being performed in the memory device, the scheduler, when an oldest request in the request queue is a write request, creates a write command based on the oldest write request.

16. The memory controller of claim 15, wherein the scheduler creates the write command based on the oldest write request and write requests for memory cells that can be written at the same time with the oldest write request.

17. A memory module comprising:
the memory controller according to claim 1; and
the memory device.

18. A processor comprising a memory controller according to claim 1, wherein the processor is connected to the memory device through a system bus.
